(19) United States
(12) Patent Application Publication
(10) Pub. No.: US 2026/0231447 A1
(43) Pub. Date: Aug. 6, 2026

(54) HIGH CAPACITY CAPACITOR AND METHOD FOR MANUFACTURING THE SAME

(71) Applicant: DB HiTek Co., Ltd., Seoul (KR)

(72) Inventors: Chulwoo HWANG, Chungcheongbuk-do (KR); Changhun HAN, Icheon-si (KR)

(21) Appl. No.: 19/085,340

(22) Filed: Mar. 20, 2025

(30) Foreign Application Priority Data
Feb. 3, 2025 (KR) 10-2025-0013173

(51) Int. Cl. H10D 1/68; H01L 23/544; H10D 1/00

(52) U.S. Cl. CPC H10D 1/716; H10D 1/041; H10W 46/00; H10W 46/401

(57) ABSTRACT

A high-capacity capacitor is proposed. The capacitor may include a first trench capacitor formed in a first trench extending in a first direction. The capacitor may also include a second trench capacitor formed in a second trench spaced apart from the first trench and extending in the first direction. The capacitor may further include a third trench capacitor formed in a third trench spaced apart from the first trench and the second trench and extending in the first direction between the first trench and the second trench. A depth of the third trench may be less than a depth of the first trench and a depth of the second trench.

### CROSS-REFERENCE TO RELATED APPLICATION

This application claims priority under 35 U.S. C § 119 to Korean Patent Application No. 10-2025-0013173 filed on Feb. 3, 2025, in the Korean Intellectual Property Office, the entire contents of which are hereby incorporated by reference.

### BACKGROUND

### Technical Field

The disclosure relates to a high-capacity capacitor and a method for manufacturing the same.

### Description of Related Technology

As the semiconductor industry moves toward ever smaller, higher-performance integrated circuits (ICs), the demand for high-capacity capacitors is increasing greatly. These capacitors are used as essential components in a variety of IC applications, such as memory storage, power management, and signal processing. Modern electronic devices require capacitors with high energy storage density in order to meet the demand for miniaturization while maintaining high performance and reliability.

### SUMMARY

One aspect is a high-capacity capacitor and a method for manufacturing the same.

Another aspect is a high-capacity capacitor that comprises: a first trench capacitor formed in a first trench extending in a first direction, a second trench capacitor formed in a second trench spaced apart from the first trench and extending in the first direction, and a third trench capacitor formed in a third trench spaced apart from the first trench and the second trench and extending in the first direction between the first trench and the second trench, wherein a depth of the third trench is less than a depth of the first trench and a depth of the second trench.

According to some aspects, the first trench capacitor comprises: a first electrode layer formed conformally in the first trench; a first dielectric layer formed conformally on the first electrode layer in the first trench; and a second electrode layer formed on the first dielectric layer in the first trench and filling up the first trench.

According to some aspects, the third trench capacitor comprises: the first electrode layer formed conformally in the third trench; the first dielectric layer formed conformally on the first electrode layer in the third trench; and the second electrode layer formed on the first dielectric layer in the third trench and filling up the third trench.

According to some aspects, the first trench capacitor comprises: a first electrode layer formed conformally in the first trench; a first dielectric layer formed conformally on the first electrode layer in the first trench; a second electrode layer formed conformally on the first dielectric layer in the first trench; a second dielectric layer formed conformally on the second electrode layer in the first trench; and a third electrode layer formed on the second dielectric layer in the first trench and filling up the first trench.

According to some aspects, the third trench capacitor comprises: the first electrode layer formed conformally in the third trench; the first dielectric layer formed conformally on the first electrode layer in the third trench; and the second electrode layer formed on the first dielectric layer in the third trench and filling up the third trench.

According to some aspects, the third trench capacitor comprises: the first electrode layer formed conformally in the third trench; the first dielectric layer formed conformally on the first electrode layer in the third trench; the second electrode layer formed conformally on the first dielectric layer in the third trench; the second dielectric layer formed conformally on the second electrode layer in the third trench; and the third electrode layer formed on the second dielectric layer in the third trench and filling up the third trench.

According to some aspects, a width of the third trench is less than a width of the first trench and a width of the second trench.

Another aspect is a high-capacity capacitor that comprises: a plurality of deep trench capacitors extending in a first direction and spaced apart from each other in a second direction; and a plurality of sub-trench capacitors formed between the plurality of deep trench capacitors, extending in the first direction, and spaced apart from each other in the second direction, wherein a trench depth of each of the plurality of deep trench capacitors is greater than a trench depth of each of the plurality of sub-trench capacitors.

According to some aspects, each of the plurality of deep trench capacitors comprises: a first electrode layer formed on a first trench formed in a substrate; a first dielectric layer formed on the first electrode layer; and a second electrode layer formed on the first dielectric layer and filling up the first trench.

According to some aspects, each of the plurality of sub-trench capacitors comprises: the first electrode layer formed on a second trench formed in the substrate; the first dielectric layer formed on the first electrode layer in the second trench; and the second electrode layer formed on the first dielectric layer and filling up the second trench.

According to some aspects, each of the plurality of deep trench capacitors comprises: a first electrode layer formed on a first trench formed in a substrate; a first dielectric layer formed on the first electrode layer; a second electrode layer formed on the first dielectric layer; a second dielectric layer formed on the second electrode layer; and a third electrode layer formed on the second dielectric layer and filling up the first trench.

According to some aspects, each of the plurality of sub-trench capacitors comprises: the first electrode layer formed on a second trench formed in the substrate; the first dielectric layer formed on the first electrode layer in the second trench; and the second electrode layer formed on the first dielectric layer and filling up the second trench.

According to some aspects, each of the plurality of sub-trench capacitors comprises: the first electrode layer formed on a second trench formed in the substrate; the first dielectric layer formed on the first electrode layer in the second trench; the second electrode layer formed on the first dielectric layer in the second trench; the second dielectric layer formed on the second electrode layer in the second trench; and the third electrode layer formed on the second dielectric layer and filling up the second trench.

Another aspect is a high-capacity capacitor that comprises: a substrate, a first trench extended in a first direction and formed in the substrate, and the first trench has a first depth, a second trench extended in the first direction, formed in the substrate and spaced apart from the first trench in a second direction, and the second trench has a second depth, a first electrode layer formed conformally on a top surface of the substrate, on the first trench, and on the second trench, a first dielectric layer formed conformally on the first electrode layer; and a second electrode layer formed on the first dielectric layer, wherein the first depth is greater than the second depth.

According to some aspects, a second dielectric layer formed on the second electrode layer; and a third electrode layer formed on the second dielectric layer.

According to some aspects, the second dielectric layer and the third electrode layer are formed in the first trench, and the second dielectric layer and the third electrode layer are not formed in the second trench.

According to some aspects, the third electrode layer is formed to fill up the first trench, and the second electrode layer is formed to fill up the second trench.

Another aspect is a high-capacity capacitor that comprises: a deep trench capacitor having a first capacity formed in a plurality of first trenches, and a sub-trench capacitor having a second capacity formed in a second trench between the plurality of first trenches, wherein the high-capacity capacitor comprises, a first electrode layer formed conformally on the first trench and the second trench, a first dielectric layer formed on the first electrode layer; and a second electrode layer formed on the first dielectric layer.

Another aspect is a method of manufacturing a high-capacity capacitor, that comprises: forming a first trench extending in a first direction in a substrate with a first depth, forming a second trench extending in the first direction in the substrate with the first depth, forming a third trench extending in the first direction in the substrate with a second depth, forming a first electrode layer conformally on the first trench to the third trench; forming a first dielectric layer conformally on the first electrode layer, and forming a second electrode layer on the first dielectric layer, wherein the first depth is less than the second depth, and the third trench is formed between the first trench and the second trench.

According to some aspects, the substrate comprises a capacitor region in which the first trench to the third trench are formed, and a photokey region in which a photokey for identifying a region to be etched is formed, and wherein the forming the first trench and the forming the second trench are processed simultaneously with a process of forming the photokey.

The aspects of the present disclosure are not limited to those described herein, and other aspects and advantages of the present disclosure that have not been mentioned can be understood by the following description and will be more clearly understood by the embodiments of the present disclosure. Moreover, it will be readily appreciated that the aspects and advantages of the present disclosure can be realized by the means set forth in the claims and combinations thereof.

The high-capacity capacitor and the method for manufacturing the same according to some embodiments of the present disclosure can significantly improve the capacitance of the entire structure without requiring extreme aspect ratios or critical dimensions.

The high-capacity capacitor and the method for manufacturing the same according to some embodiments of the present disclosure can improve capacitance density with an increased available surface area in the same area.

The high-capacity capacitor and the method for manufacturing the same according to some embodiments of the present disclosure can mitigate manufacturing difficulties due to high aspect ratios by using sub-trenches having a depth less than that of deep trenches.

The high-capacity capacitor and the method for manufacturing the same according to some embodiments of the present disclosure can improve productivity by simplifying the manufacturing process and reducing the risk of defect occurrence with relaxed aspect ratio and critical dimension (CD) requirements.

The high-capacity capacitor and the method for manufacturing the same according to some embodiments of the present disclosure can provide a scalable and manufacturable solution for realizing high-capacity capacitors required in high-performance IC applications, and contribute to the miniaturization and performance improvement of semiconductor devices.

In addition to what has been described above, specific effects of the present disclosure will be described together while describing specific details for carrying out the present disclosure below.

### BRIEF DESCRIPTION OF THE DRAWINGS

FIG. 1 is a plan view for describing a high-capacity capacitor according to some embodiments of the present disclosure.

FIG. 2 is a cross-sectional view taken along line A-A′ of FIG. 1.

FIG. 3 shows a cross-section of a high-capacity capacitor according to some other embodiments of the present disclosure.

FIG. 4 shows a cross-section of a high-capacity capacitor according to some other embodiments of the present disclosure.

FIGS. 5 to 8 are diagrams for describing a method of manufacturing a high-capacity capacitor according to some embodiments of the present disclosure.

FIGS. 9 to 12 are diagrams for describing a method of manufacturing a high-capacity capacitor according to some other embodiments of the present disclosure.

### DETAILED DESCRIPTION

Traditional capacitor designs have had difficulty meeting these needs due to limitations in size reduction and energy density. To resolve this issue, deep trench capacitors (DTCs) have been introduced, which provide a larger surface area per unit area by etching deep and narrow trenches into silicon substrates. This design enables high capacitance in a small area, bringing about a revolutionary change in semiconductor technology.

However, deep trench capacitors also have some important limitations. First, deep trench capacitors have a limitation in the ratio of the depth and width of the trench, i.e., the aspect ratio, required to secure sufficient capacitance. The trenches need to be made deep and narrow in order to maximize capacitance, but there are drawbacks that a high aspect ratio can make it difficult to form a uniform and precise trench profile and minute variations in the depth or width of the trench can have a significant impact on the performance and reliability of the capacitor. In addition, as the trench width becomes narrower, it is essential to precisely control the critical dimension (CD), which can be a significant challenge in the production process. Furthermore, a high aspect ratio makes it difficult to uniformly deposit dielectric materials and electrodes inside the trench, which can lead to problems such as voids or incomplete filling, resulting in a drawback of limitations in capacitance.

To overcome these limitations, the present disclosure proposes a novel high-capacity capacitor structure. This design will be able to overcome the limitations of the existing structures by including additional parallel sub-trench capacitors between the main deep trench capacitors.

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

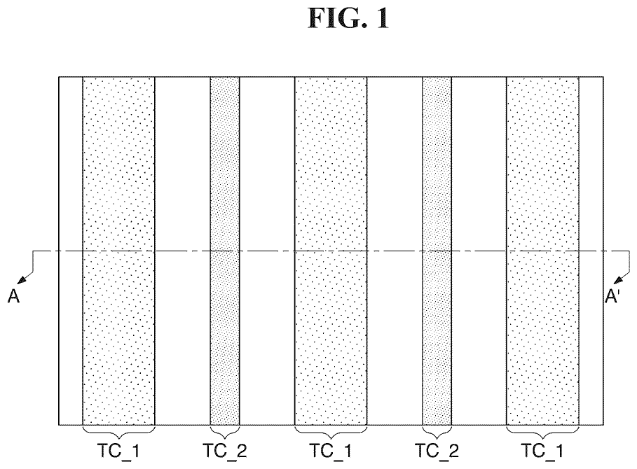

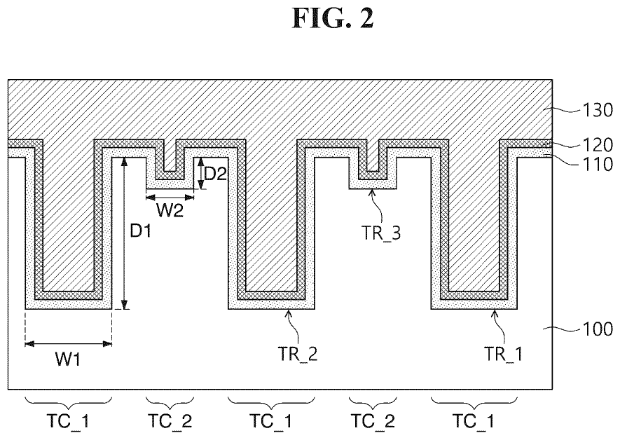

FIG. 1 is a plan view for describing a high-capacity capacitor according to some embodiments of the present disclosure. FIG. 2 is a cross-sectional view taken along line A-A′ of FIG. 1.

Referring to FIG. 1, a high-capacity capacitor according to some embodiments of the present disclosure may include a first trench capacitor TC_1 and a second trench capacitor TC_2. According to some embodiments, the first trench capacitor TC_1 may be a deep trench capacitor, and the second trench capacitor TC_2 may be a sub-trench capacitor. In the present disclosure, for convenience of description, a capacitor structure using a relatively deeper trench is defined as a deep trench capacitor, and a capacitor structure using a relatively shallower trench is defined as a sub-trench capacitor, but embodiments are not limited by these terms.

According to some embodiments, the high-capacity capacitor may include one or more first trench capacitors TC_1 and one or more second trench capacitors TC_2. The high-capacity capacitor is described herein as including three first trench capacitors TC_1 and two second trench capacitors TC_2 for convenience of description, but embodiments are not limited by the numbers of first trench capacitors TC_1 and second trench capacitors TC_2.

The first trench capacitors TC_1 may extend in a first direction. The first trench capacitors TC_1 may be spaced apart from the neighboring first trench capacitors TC_1 in a second direction. For example, with reference to FIG. 2, the first trench capacitors TC_1 may extend in the vertical direction and be spaced apart from the neighboring first trench capacitors TC_1 in the left and right directions. The fact that a first trench capacitor TC_1 and neighboring first trench capacitors TC_1 are spaced apart from each other in the second direction may mean that the trench included in the first trench capacitor TC_1 and the trenches included in the neighboring first trench capacitors TC_1 are spaced apart from each other, and the components of the actual first trench capacitors TC_1 may be connected to each other.

The second trench capacitors TC_2 may extend in the first direction. A second trench capacitor TC_2 may be spaced apart from the neighboring second trench capacitor TC_2 in the second direction. A second trench capacitor TC_2 may be disposed between a first trench capacitor TC_1 and a first trench capacitor TC_1 neighboring thereto. In other words, the first trench capacitors TC_1 and the second trench capacitors TC_2 may be disposed alternately.

Referring to FIG. 2, the first trench capacitors TC_1 and the second trench capacitors TC_2 may be disposed alternately. That is, a sub-trench in which a second trench capacitor TC_2 is formed can be formed between a deep trench in which a first trench capacitor TC_1 is formed and a deep trench neighboring thereto. Likewise, a deep trench may be formed between a sub-trench and a sub-trench neighboring thereto. Although FIG. 2 shows that the deep trenches and the sub-trenches are disposed alternately in a ratio of 1:1, embodiments are not limited thereto. For example, two or more sub-trenches may be disposed between the deep trenches depending on the design needs.

A first width W1 of the deep trench may be greater than a second width W2 of the sub-trench. In addition, a first depth D1 of the deep trench may be greater than a second depth D2 of the sub-trench. Furthermore, the aspect ratio of the deep trench may be greater than the aspect ratio of the sub-trench. According to some embodiments, the second trench capacitors TC_2 using the sub-trench can secure a higher capacitance in the same area by increasing the total surface area of the high-capacity capacitor structure. That is, the high-capacity capacitor has the advantage of being able to secure the required capacitance by adding the second trench capacitors TC_2 in addition to increasing the aspect ratio of the first trench capacitors TC_1 in order to secure the capacitance. Therefore, the high-capacity capacitor according to some embodiments can secure a high capacitance without excessively increasing the aspect ratio of the first trench capacitors TC_1, resulting in advantages of reducing challenges in the manufacturing process and enabling easier uniform trench formation and deposition processes. Next, a more specific configuration of the high-capacity capacitor will be described.

First, a substrate 100 may have deep trenches and sub-trenches formed therein. A first trench TR_1 and a second trench TR_2 may be deep trenches, and a third trench TR_3 may be a sub-trench. The first trench TR_1 and the second trench TR_2 may be spaced apart in the second direction. In other words, a deep trench and its neighboring deep trench may be spaced apart in the second direction. Similarly, a sub-trench and its neighboring sub-trench may also be spaced apart in the second direction. The third trench TR_3 may be formed between the first trench TR_1 and the second trench TR_2. The width of the third trench TR_3 may be less than the width of the first trench TR_1 and the width of the second trench TR_2. In addition, the depth of the third trench TR_3 may be less than the depth of the first trench TR_1 and the depth of the second trench TR_2.

A first electrode layer 110 may be formed on the substrate 100. More specifically, the first electrode layer 110 may be formed along the top surface of the substrate 100 and the profiles of the first trench TR_1 to the third trench TR_3. More specifically, the first electrode layer 110 may be formed conformally on the first trench TR_1 of the substrate 100. In addition, the first electrode layer 110 may be formed conformally on the second trench TR_2 of the substrate 100. Furthermore, the first electrode layer 110 may be formed conformally on the third trench TR_3 of the substrate 100.

According to some embodiments, the substrate 100 may be a silicon (Si) substrate. However, this is merely an example and embodiments are not limited thereto. For example, the substrate 100 may be implemented using at least one of gallium arsenide (GaAs), sapphire (Al2O3), silicon carbide (SiC), indium phosphide (InP), a polymer, and an organic substrate.

The first electrode layer 110 may include at least one of aluminum (Al), copper (Cu), silver (Ag), gold (Au), nickel (Ni), tungsten (W) alloy, titanium-nickel (TiNi) alloy, chromium-copper (CrCu) alloy, indium tin oxide (ITO), ruthenium dioxide (RuO₂), and iridium oxide (IrO₂), but these are examples, and embodiments are not limited thereto.

A first dielectric layer 120 may be formed on the first electrode layer 110. Specifically, the first dielectric layer 120 may be formed along the profile of the first electrode layer 110 formed on the substrate 100. The first dielectric layer 120 may be formed conformally on the first electrode layer 110 in the first trench TR_1. In addition, the first dielectric layer 120 may be formed conformally on the first electrode layer 110 in the second trench TR_2. Furthermore, the first dielectric layer 120 may be formed conformally on the first electrode layer 110 in the third trench TR_3.

According to some embodiments, the first dielectric layer 120 may include at least one of silicon dioxide (SiO₂), fluorinated silicon dioxide (FSG), polyimide, aluminum oxide (Al₂O₃), silicon nitride (Si₃N₄), silicon oxynitride (SiON), hafnium oxide (HfO₂), zirconium oxide (ZrO₂), titanium dioxide (TiO₂), tantalum oxide (Ta₂O₅), lanthanum oxide (La₂O₃), and yttrium oxide (Y₂O₃), but these are merely examples, and embodiment is not limited thereto.

A second electrode layer 130 may be formed on the first dielectric layer 120. Specifically, the second electrode layer 130 may be formed to fill up all of the first trench TR_1 to the third trench TR_3 formed on the substrate 100. The second electrode layer 130 may be formed on the first dielectric layer 120 to fill up the first trench TR_1. In addition, the second electrode layer 130 may be formed on the first dielectric layer 120 to fill up the second trench TR_2. Furthermore, the second electrode layer 130 may be formed on the first dielectric layer 120 to fill up the third trench TR_3.

The second electrode layer 130 may include at least one of aluminum (Al), copper (Cu), silver (Ag), gold (Au), nickel (Ni), tungsten (W) alloy, titanium-nickel (TiNi) alloy, chromium-copper (CrCu) alloy, indium tin oxide (ITO), ruthenium dioxide (RuO₂), and iridium oxide (IrO₂), but these are examples, and embodiments are not limited thereto.

In summary, the first trench TR_1 and the second trench TR_2 having relatively larger width and depth may be formed in the substrate 100, and the third trench TR_3 having relatively smaller width and depth may be formed between the first trench TR_1 and the second trench TR_2. In a high-capacity capacitor according to some embodiments, the first electrode layer 110 and a second dielectric layer 140 are formed conformally along the top surface of the substrate 100 and the profiles of the first trench TR_1 to the third trench TR_3, and the second electrode layer 130 may be formed to fill up all of the first trench TR_1 to the third trench TR_3.

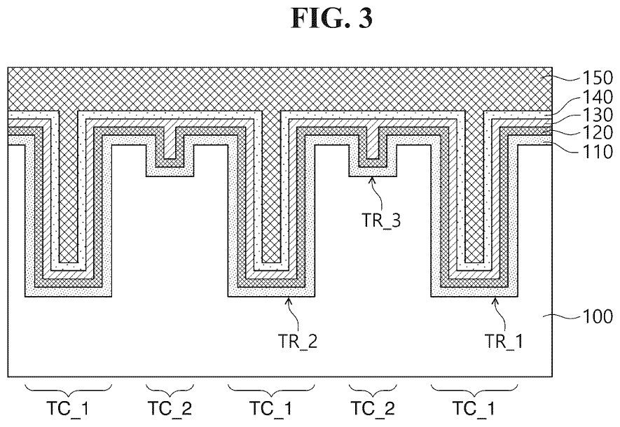

FIG. 3 shows a cross-section of a high-capacity capacitor according to some other embodiments of the present disclosure. For convenience of description, the same or similar contents as those described above will be omitted or described briefly.

Referring to FIG. 3, a first trench TR_1 and a second trench TR_2, which are deep trenches, and a third trench TR_3, which is a sub-trench, may be formed in a substrate 100. The third trench TR_3 may be formed between the first trench TR_1 and the second trench TR_2.

A first electrode layer 110 may be formed on the substrate 100. Specifically, the first electrode layer 110 may be formed along the top surface of the substrate 100 and the profiles of the first trench TR_1 to the third trench TR_3. That is, the first electrode layer 110 may be formed conformally on the first trench TR_1 of the substrate 100. In addition, the first electrode layer 110 may be formed conformally on the second trench TR_2 of the substrate 100. Moreover, the first electrode layer 110 may be formed conformally on the third trench TR_3 of the substrate 100.

A first dielectric layer 120 may be formed on the first electrode layer 110. Specifically, the first dielectric layer 120 may be formed along the profile of the first electrode layer 110 formed on the substrate 100. The first dielectric layer 120 may be formed conformally on the first electrode layer 110 in the first trench TR_1. In addition, the first dielectric layer 120 may be formed conformally on the first electrode layer 110 in the second trench TR_2. Further, the first dielectric layer 120 may be formed conformally on the first electrode layer 110 in the third trench TR_3.

A second electrode layer 130 may be formed on the first dielectric layer 120. Specifically, the second electrode layer 130 on the first trench TR_1 and the second trench TR_2, which are deep trenches, may be formed conformally along the profile of the first dielectric layer 120 formed in the first trench TR_1 and the second trench TR_2. In addition, the second electrode layer 130 on the third trench TR_3, which is a sub-trench, may be formed to fill up the entire third trench TR_3.

A second dielectric layer 140 may be formed on the second electrode layer 130. Specifically, the second dielectric layer 140 on the first trench TR_1 and the second trench TR_2 may be formed conformally along the profile of the second electrode layer 130 in the first trench TR_1 and the second trench TR_2. In addition, the second dielectric layer 140 on the third trench TR_3 may be formed along the profile of the second electrode layer 130 on the third trench TR_3 since the third trench TR_3 is filled up with the second electrode layer 130.

According to some embodiments, the second dielectric layer 140 may include at least one of silicon dioxide (SiO₂), fluorinated silicon dioxide (FSG), polyimide, aluminum oxide (Al₂O₃), silicon nitride (Si₃N₄), silicon oxynitride (SiON), hafnium oxide (HfO₂), zirconium oxide (ZrO₂), titanium dioxide (TiO₂), tantalum oxide (Ta₂O₅), lanthanum oxide (La₂O₃), and yttrium oxide (Y₂O₃), but these are merely examples, and embodiments are not limited thereto.

A third electrode layer 150 may be formed on the second dielectric layer 140. The third electrode layer 150 on the first trench TR_1 and the second trench TR_2 may be formed on the second dielectric layer 140 to fill up the first trench TR_1 and the second trench TR_2. The third electrode layer 150 on the third trench TR_3 may be formed along the profile of the second dielectric layer 140.

The third electrode layer 150 may include at least one of aluminum (Al), copper (Cu), silver (Ag), gold (Au), nickel (Ni), tungsten (W) alloy, titanium-nickel (TiNi) alloy, chromium-copper (CrCu) alloy, indium tin oxide (ITO), ruthenium dioxide (RuO₂), and iridium oxide (IrO₂), but these are examples, and embodiments are not limited thereto.

In summary, the first trench TR_1 and the second trench TR_2 having relatively larger width and depth may be formed in the substrate 100, and the third trench TR_3 having relatively smaller width and depth may be formed between the first trench TR_1 and the second trench TR_2. In a high-capacity capacitor according to some embodiments, the first trench capacitor TC_1, which is a deep trench capacitor, may have a double MIM (metal-insulator-metal) structure, and the second trench capacitor TC_2, which is a sub-trench capacitor, may have a single MIM structure.

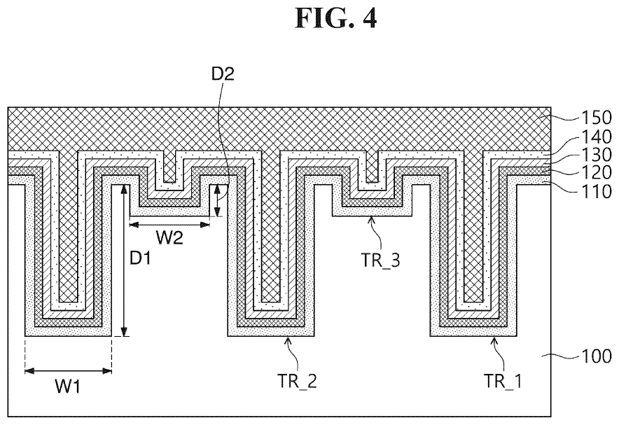

FIG. 4 shows a cross-section of a high-capacity capacitor according to some other embodiments of the present disclosure. For convenience of description, the same or similar contents as those described above will be omitted or described briefly.

Referring to FIG. 4, a first trench TR_1 and a second trench TR_2, which are deep trenches, and a third trench TR_3, which is a sub-trench, may be formed in a substrate 100. The third trench TR_3 may be formed between the first trench TR_1 and the second trench TR_2.

A first electrode layer 110 may be formed on the substrate 100. Specifically, the first electrode layer 110 may be formed along the top surface of the substrate 100 and the profiles of the first trench TR_1 to the third trench TR_3. That is, the first electrode layer 110 may be formed conformally on the first trench TR_1 of the substrate 100. In addition, the first electrode layer 110 may be formed conformally on the second trench TR_2 of the substrate 100. Furthermore, the first electrode layer 110 may be formed conformally on the third trench TR_3 of the substrate 100.

A first dielectric layer 120 may be formed on the first electrode layer 110. Specifically, the first dielectric layer 120 may be formed along the profile of the first electrode layer 110 formed on the substrate 100. The first dielectric layer 120 may be formed conformally on the first electrode layer 110 in the first trench TR_1. In addition, the first dielectric layer 120 may be formed conformally on the first electrode layer 110 in the second trench TR_2. Furthermore, the first dielectric layer 120 may be formed conformally on the first electrode layer 110 in the third trench TR_3.

A second electrode layer 130 may be formed on the first dielectric layer 120. Specifically, the second electrode layer 130 may be formed along the profile of the first dielectric layer 120 formed on the substrate 100. The second electrode layer 130 may be formed conformally on the first dielectric layer 120 in the first trench TR_1. In addition, the second electrode layer 130 may be formed conformally on the first dielectric layer 120 in the second trench TR_2. Furthermore, the second electrode layer 130 may be formed conformally on the first dielectric layer 120 in the third trench TR_3.

A second dielectric layer 140 may be formed on the second electrode layer 130. Specifically, the second dielectric layer 140 may be formed along the profile of the second electrode layer 130 formed on the substrate 100. The second dielectric layer 140 may be formed conformally on the second electrode layer 130 in the first trench TR_1. In addition, the second dielectric layer 140 may be formed conformally on the second electrode layer 130 in the second trench TR_2. Furthermore, the second dielectric layer 140 may be formed conformally on the second electrode layer 130 in the third trench TR_3.

A third electrode layer 150 may be formed on the second dielectric layer 140. The third electrode layer 150 may be formed on the second dielectric layer 140 to fill up all of the first trench TR_1 to the third trench TR_3.

In summary, the first trench TR_1 and the second trench TR_2 having relatively larger width and depth may be formed in the substrate 100, and the third trench TR_3 having relatively smaller width and depth may be formed between the first trench TR_1 and the second trench TR_2. In a high-capacity capacitor according to some embodiments, both the first trench capacitor TC_1, which is a deep trench capacitor, and the second trench capacitor TC_2, which is a sub-trench capacitor, may have a double MIM structure. However, the second width W2 of the sub-trench in FIG. 4 may be greater than the second width W2 of the sub-trench in FIG. 1 for the formation of the double MIM structure, but embodiments are not limited thereto. Those having ordinary skill in the art will be able to achieve the objects of the present disclosure by forming sub-trenches having various widths and depths according to design needs without departing from the scope of the present disclosure.

According to some embodiments, the cross-sectional area of the first trench capacitor TC_1 may be greater than the cross-sectional area of the second trench capacitor TC_2. In other words, the capacity of the first trench capacitor TC_1 may be greater than the capacity of the second trench capacitor TC_2. On the other hand, the second trench capacitor TC_2 may be structurally more stable as it has a smaller aspect ratio than the first trench capacitor TC_1. Therefore, the high-capacity capacitor according to some embodiments of the present disclosure has the advantage of being able to maximize the capacity of the capacitor while ensuring structural stability to the maximum extent by disposing the structurally stable second trench capacitor TC_2 between the first trench capacitors TC_1 having a relatively larger capacity.

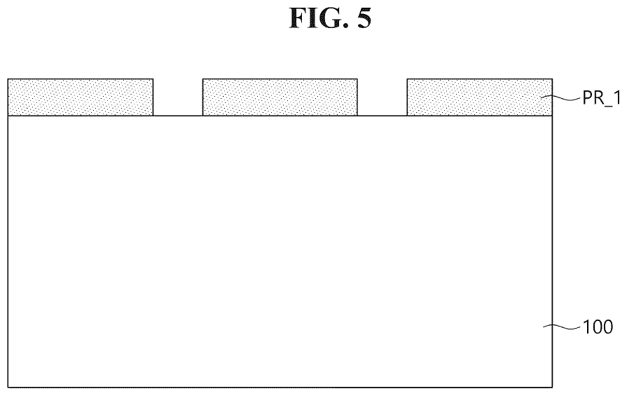

FIGS. 5 to 8 are diagrams for describing a method of manufacturing a high-capacity capacitor according to some embodiments of the present disclosure.

Referring to FIG. 5, first, a first etching pattern PR_1 for forming a third trench TR_3 may be formed on a substrate 100. For example, the first etching pattern PR_1 may be formed through an exposure process using an appropriate mask after applying a photoresist on the substrate 100, but embodiments are not limited thereto.

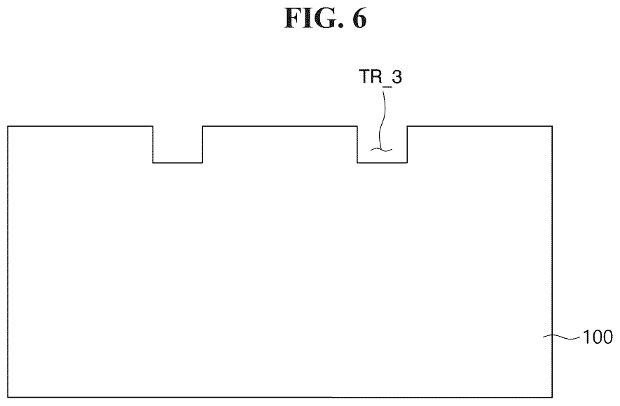

Referring to FIG. 6, a third trench TR_3 may be formed in the substrate 100 by using the first etching pattern PR_1, and the first etching pattern PR_1 may then be removed. For example, the third trench TR_3 may be formed using a process such as wet etching or dry etching by using the first etching pattern PR_1. At this time, the first etching pattern PR_1 may be removed together while forming the third trench TR_3, or may be removed in a process separate from the formation of the third trench TR_3.

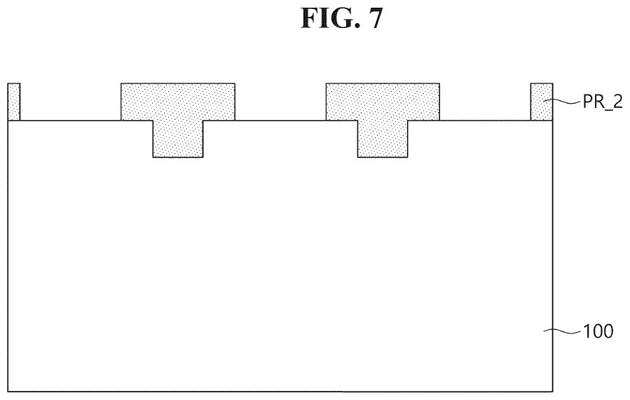

Referring to FIG. 7, a second etching pattern PR_2 for forming a first trench TR_1 and a second trench TR_2 may be formed on the substrate 100. For example, the second etching pattern PR_2 may be formed through an exposure process using an appropriate mask after applying a photoresist on the substrate 100, but embodiments are not limited thereto.

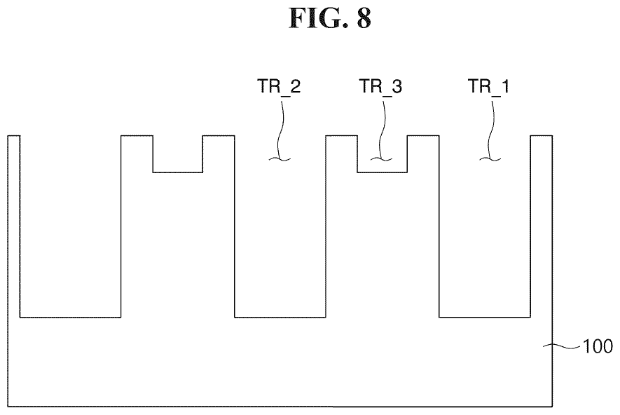

Referring to FIG. 8, the first trench TR_1 and the second trench TR_2 may be formed in the substrate 100 by using the second etching pattern PR_2, and the second etching pattern PR_2 may then be removed. When the second etching pattern PR_2 is removed, the first trench TR_1 to the third trench TR_3 may all be exposed. After forming the first trench TR_1 to the third trench TR_3 in the substrate 100, a first electrode layer 110, a first dielectric layer 120, a second electrode layer 130, a second dielectric layer 140, and/or a third electrode layer 150 may be formed as shown in FIGS. 2 to 4, thereby manufacturing a high-capacity capacitor including a first trench capacitor TC_1 and a second trench capacitor TC_2.

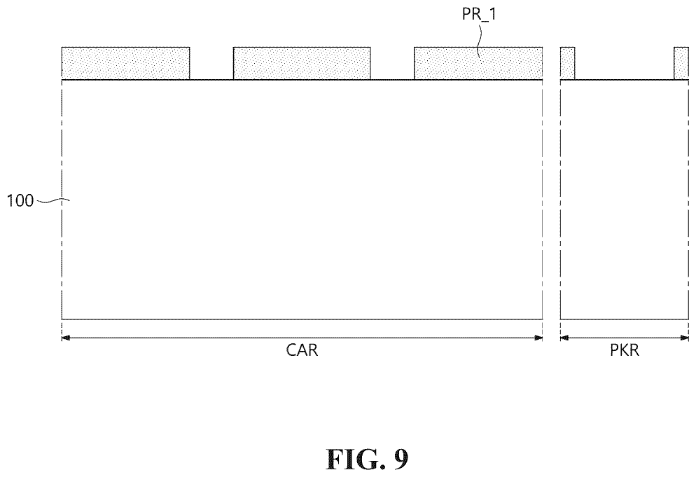

FIGS. 9 to 12 are diagrams for describing a method of manufacturing a high-capacity capacitor according to some other embodiments of the present disclosure.

Referring to FIG. 9, a substrate 100 may include a capacitor array region CAR in which a first trench capacitor TC_1 and a second trench capacitor TC_2 are to be formed, and a photokey region PKR in which a photokey is to be formed. The photokey may refer to an element that serves as a reference used to form a particular pattern or align a process in a semiconductor manufacturing process. Photokeys are mainly utilized in photolithography processes, and may play an important role in accurately aligning multiple layers on the substrate 100 or controlling a fabrication process. Photokeys may be used to help with precise alignment between layers and to minimize the occurrence of defects while maintaining process quality.

A first etching pattern PR_1 may include a pattern for forming a photokey. In other words, the first etching pattern PR_1 may be a pattern for forming a third trench TR_3 and a photokey PK. That is, the process of forming the photokey and the process of forming the third trench TR_3 may be performed simultaneously.

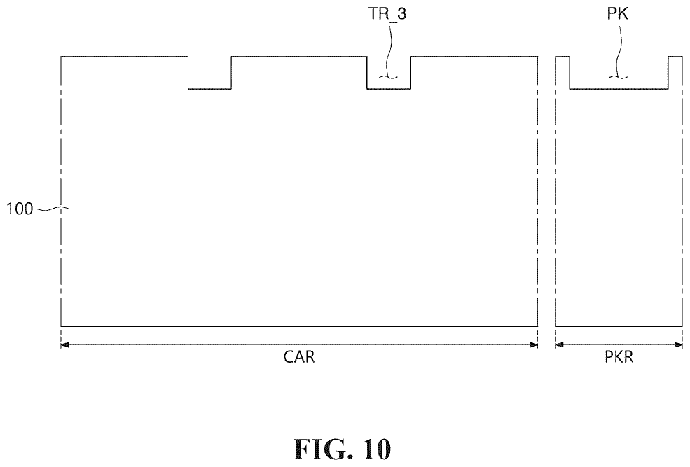

Referring to FIG. 10, the third trench TR_3 may be formed in the capacitor array region CAR and the photokey PK may be formed in the photokey region PKR by using the first etching pattern PR_1. Next, the first etching pattern PR_1 may be removed. As with the foregoing, the first etching pattern PR_1 may be removed together with the process of forming the third trench TR_3 and the photokey PK, or may be removed separately after the third trench TR_3 and the photokey PK are formed.

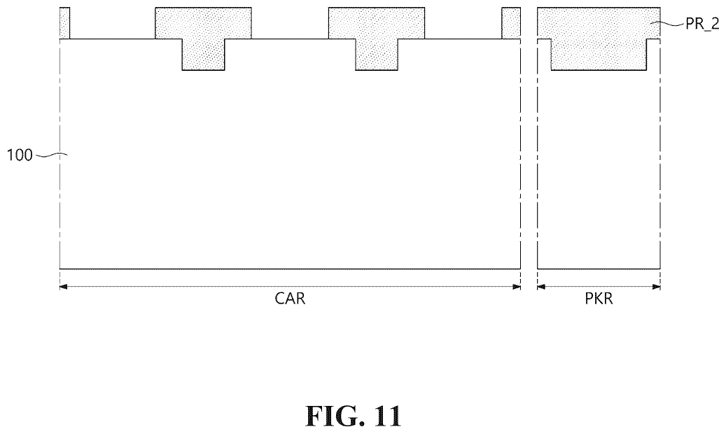

Referring to FIG. 11, a second etching pattern PR_2 for forming a first trench TR_1 and a second trench TR_2 may be formed on the capacitor array region CAR of the substrate 100.

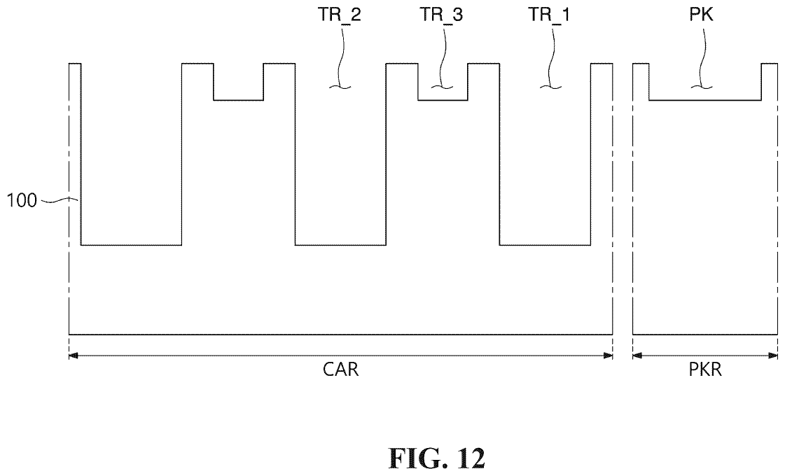

Referring to FIG. 12, the first trench TR_1 and the second trench TR_2 may be formed in the substrate 100 by using the second etching pattern PR_2, and the second etching pattern PR_2 may then be removed. When the second etching pattern PR_2 is removed, the first trench TR_1 to the third trench TR_3 and the photokey PK may all be exposed. After forming the first trench TR_1 to the third trench TR_3 in the substrate 100, a first electrode layer 110, a first dielectric layer 120, a second electrode layer 130, a second dielectric layer 140, and/or a third electrode layer 150 may be formed as shown in FIGS. 2 to 4, thereby manufacturing a high-capacity capacitor including a first trench capacitor TC_1 and a second trench capacitor TC_2.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A high-capacity capacitor comprising:
a first trench capacitor formed in a first trench extending in a first direction;
a second trench capacitor formed in a second trench spaced apart from the first trench and extending in the first direction; and
a third trench capacitor formed in a third trench spaced apart from the first trench and the second trench and extending in the first direction between the first trench and the second trench,
wherein a depth of the third trench is less than a depth of the first trench and a depth of the second trench.

2. The high-capacity capacitor of claim 1, wherein the first trench capacitor comprises:
a first electrode layer formed conformally in the first trench;
a first dielectric layer formed conformally on the first electrode layer in the first trench; and
a second electrode layer formed on the first dielectric layer in the first trench and filling up the first trench.

3. The high-capacity capacitor of claim 2, wherein the third trench capacitor comprises:
the first electrode layer formed conformally in the third trench;
the first dielectric layer formed conformally on the first electrode layer in the third trench; and
the second electrode layer formed on the first dielectric layer in the third trench and filling up the third trench.

4. The high-capacity capacitor of claim 1, wherein the first trench capacitor comprises:
a first electrode layer formed conformally in the first trench;
a first dielectric layer formed conformally on the first electrode layer in the first trench;
a second electrode layer formed conformally on the first dielectric layer in the first trench;
a second dielectric layer formed conformally on the second electrode layer in the first trench; and
a third electrode layer formed on the second dielectric layer in the first trench and filling up the first trench.

5. The high-capacity capacitor of claim 4, wherein the third trench capacitor comprises:
the first electrode layer formed conformally in the third trench;
the first dielectric layer formed conformally on the first electrode layer in the third trench; and
the second electrode layer formed on the first dielectric layer in the third trench and filling up the third trench.

6. The high-capacity capacitor of claim 4, wherein the third trench capacitor comprises:
the first electrode layer formed conformally in the third trench;
the first dielectric layer formed conformally on the first electrode layer in the third trench;
the second electrode layer formed conformally on the first dielectric layer in the third trench;
the second dielectric layer formed conformally on the second electrode layer in the third trench; and
the third electrode layer formed on the second dielectric layer in the third trench and filling up the third trench.

7. The high-capacity capacitor of claim 1, wherein a width of the third trench is less than a width of the first trench and a width of the second trench.

8. A high-capacity capacitor comprising:
a plurality of deep trench capacitors extending in a first direction and spaced apart from each other in a second direction; and
a plurality of sub-trench capacitors formed between the plurality of deep trench capacitors, extending in the first direction, and spaced apart from each other in the second direction,
wherein a trench depth of each of the plurality of deep trench capacitors is greater than a trench depth of each of the plurality of sub-trench capacitors.

9. The high-capacity capacitor of claim 8, wherein each of the plurality of deep trench capacitors comprises:
a first electrode layer formed on a first trench formed in a substrate;
a first dielectric layer formed on the first electrode layer; and
a second electrode layer formed on the first dielectric layer and filling up the first trench.

10. The high-capacity capacitor of claim 9, wherein each of the plurality of sub-trench capacitors comprises:
the first electrode layer formed on a second trench formed in the substrate;
the first dielectric layer formed on the first electrode layer in the second trench; and
the second electrode layer formed on the first dielectric layer and filling up the second trench.

11. The high-capacity capacitor of claim 8, wherein each of the plurality of deep trench capacitors comprises:
a first electrode layer formed on a first trench formed in a substrate;
a first dielectric layer formed on the first electrode layer;
a second electrode layer formed on the first dielectric layer;
a second dielectric layer formed on the second electrode layer; and
a third electrode layer formed on the second dielectric layer and filling up the first trench.

12. The high-capacity capacitor of claim 11, wherein each of the plurality of sub-trench capacitors comprises:
the first electrode layer formed on a second trench formed in the substrate;
the first dielectric layer formed on the first electrode layer in the second trench; and
the second electrode layer formed on the first dielectric layer and filling up the second trench.

13. The high-capacity capacitor of claim 11, wherein each of the plurality of sub-trench capacitors comprises:
the first electrode layer formed on a second trench formed in the substrate;
the first dielectric layer formed on the first electrode layer in the second trench;
the second electrode layer formed on the first dielectric layer in the second trench;
the second dielectric layer formed on the second electrode layer in the second trench; and
the third electrode layer formed on the second dielectric layer and filling up the second trench.

14. A high-capacity capacitor comprising:
a substrate;
a first trench extending in a first direction and formed in the substrate, the first trench having a first depth;
a second trench extending in the first direction, formed in the substrate and spaced apart from the first trench in a second direction, the second trench having a second depth;
a first electrode layer formed conformally on a top surface of the substrate, on the first trench, and on the second trench;
a first dielectric layer formed conformally on the first electrode layer; and
a second electrode layer formed on the first dielectric layer,
wherein the first depth is greater than the second depth.

15. The high-capacity capacitor of claim 14, further comprising:
a second dielectric layer formed on the second electrode layer; and
a third electrode layer formed on the second dielectric layer.

16. The high-capacity capacitor of claim 15, wherein the second dielectric layer and the third electrode layer are formed in the first trench, and
wherein the second dielectric layer and the third electrode layer are not formed
in the second trench.

17. The high-capacity capacitor of claim 16, wherein the third electrode layer is formed to fill up the first trench, and
wherein the second electrode layer is formed to fill up the second trench.

18. A high-capacity capacitor comprising:
a deep trench capacitor having a first capacity formed in a plurality of first trenches; and
a sub-trench capacitor having a second capacity formed in a second trench between the plurality of first trenches,
wherein the high-capacity capacitor comprises:
a first electrode layer formed conformally on the first trench and the second trench;
a first dielectric layer formed on the first electrode layer; and
a second electrode layer formed on the first dielectric layer.

19. A method of manufacturing a high-capacity capacitor, comprising:
forming a first trench extending in a first direction in a substrate with a first depth;
forming a second trench extending in the first direction in the substrate with the first depth;
forming a third trench extending in the first direction in the substrate with a second depth;
forming a first electrode layer conformally on the first trench to the third trench;
forming a first dielectric layer conformally on the first electrode layer; and
forming a second electrode layer on the first dielectric layer,
wherein the first depth is less than the second depth, and
wherein the third trench is formed between the first trench and the second trench.

20. The method of claim 19, wherein the substrate comprises a capacitor region in which the first trench to the third trench are formed, and a photokey region in which a photokey for identifying a region to be etched is formed, and
wherein forming the first trench and forming the second trench are simultaneously performed with forming the photokey.
